(19) United States
(12) Patent Application Publication
(10) Pub. No.: US 2011/0141691 A1
(43) Pub. Date: Jun. 16, 2011

(54) SYSTEMS AND METHODS FOR MANUFACTURING SYNTHETIC JETS

(76) Inventors: David S. SLATON, Huntsville, AL (US); David McDonald, Lacy Springs, AL (US)

(21) Appl. No.: 12/635,792

(22) Filed: Dec. 11, 2009

(51) Int. Cl. H05K 7/20; B32B 38/04

(52) U.S. Cl. 361/690; 156/252; 156/64; 156/513

(57) ABSTRACT

A method for manufacturing synthetic jets is described. The method includes forming a hole extending through a portion of a first printed circuit board (PCB), wherein the hole defines a portion the synthetic jet assembly, and wherein the hole is positioned to enable the synthetic jet assembly to facilitate cooling a component coupled to a second PCB.

### BACKGROUND OF THE INVENTION

The field of the disclosed subject matter relates generally to synthetic jets and, more particularly, to systems and methods for manufacturing synthetic jets.

### BRIEF DESCRIPTION OF THE INVENTION

As additional components are frequently coupled to the circuit board, the density of heat generating components on a circuit board continues to rise. Moreover, as the number of heat generating components is increased, concerns about proper cooling of the components is also increased. Within known circuit boards, forced cooling is used to cool the components. For example, jet impingement of air onto the heat generating components can be provided. In such cases, the jet is placed near the component desired to be cooled.

However, manufacturing a large amount of known impingement jets may be labor intensive. Moreover, coupling such jets near the heat generating component to be cooled may be a tedious task that involves manual labor. Moreover, as more electronic components are placed on the circuit board, space on the board becomes valuable and placement of any circuitry used to operate the jet on the board consumes this valuable space.

### BRIEF DESCRIPTION OF THE INVENTION

In one aspect, a method for manufacturing a synthetic jet assembly is provided. The method includes forming a hole extending through a portion of a first printed circuit board (PCB), wherein the hole defines a portion the synthetic jet assembly. The hole is positioned to enable the synthetic jet assembly to facilitate cooling a component coupled to a second PCB.

In another aspect, a synthetic jet assembly is provided, including a first printed circuit board (PCB) that includes a hole extending through a portion of the first PCB, wherein the hole defines a portion of the synthetic jet assembly. The hole is positioned to enable the synthetic jet assembly to facilitate cooling a component coupled to a second PCB.

In another aspect, a system for manufacturing a synthetic jet assembly is provided. The system includes a milling machine configured to form a hole extending through a portion of a first printed circuit board (PCB), wherein the hole defines a portion of the synthetic jet assembly, and wherein the milling machine is configured to form the hole in a positioned that enables the synthetic jet assembly to facilitate cooling a component coupled to a second PCB.

### BRIEF DESCRIPTION OF THE DRAWINGS

FIG. 1 is a block diagram of an exemplary system for use in manufacturing a synthetic jet.

FIG. 2 is a perspective view of an exemplary synthetic jet fabricated using the system shown in FIG. 1.

FIG. 3 is a top view of an exemplary printed circuit board (PCB) used with the synthetic jet shown in FIG. 2.

FIG. 4 is a bottom view of the PCB shown in FIG. 3.

FIG. 5 is a side view of the synthetic jet shown in FIG. 2.

FIG. 6 is a perspective view of an alternative embodiment of a synthetic jet that may be fabricated using the systems described herein.

FIG. 7 is a side view of another alternative embodiment of a synthetic jet.

FIG. 8 is a block diagram of an integrated circuit of the synthetic jet shown in FIG. 7.

FIG. 9 is a top view of an exemplary system including a plurality of synthetic jets.

FIG. 10 is an exploded view of an exemplary system including the synthetic jet shown in FIG. 2.

### DETAILED DESCRIPTION OF THE INVENTION

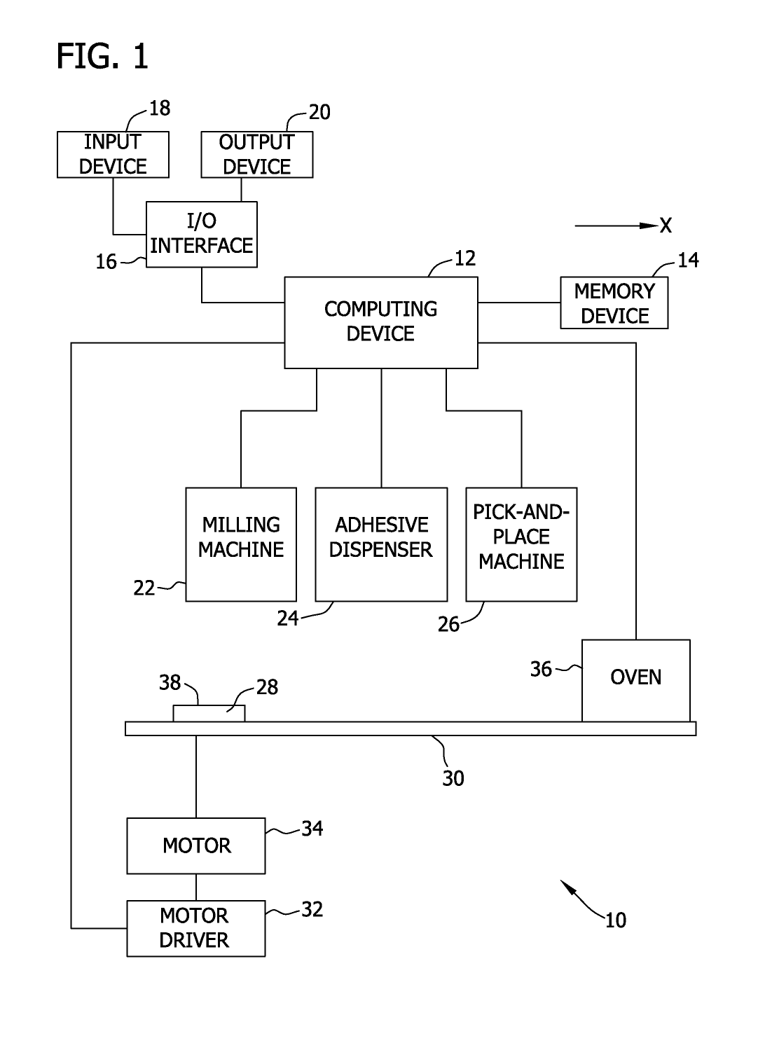

FIG. 1 is a block diagram of an exemplary system 10 for use in manufacturing a synthetic jet (not shown). In the exemplary embodiment, system 10 includes a computing device 12, a memory device 14, an input/output (I/O) interface 16, an input device 18, an output device 20, a milling machine 22, an adhesive dispenser 24, a pick-and-place machine 26, a printed circuit board (PCB) 28, a support 30, a motor driver 32, a motor 34, and an oven 36. Support 30 may be a conveyor that is operated by motor 34.

As used herein, the term “computing device” is not limited to just those integrated circuits referred to in the art as a computer, but broadly refers to a microcontroller, a microcomputer, a programmable logic controller, an application specific integrated circuit, or any other programmable circuit. The computer includes a central processing unit and may include a device, such as a floppy disk drive or a compact-disc read-only memory (CD-ROM) drive, for reading data from a computer-readable medium, such as a floppy disk, a compact disc-read only memory (CD-ROM), a magneto-optical disk (MOD), and/or a digital versatile disc (DVD). In an alternative embodiment, computing device 12 executes instructions stored in firmware. Output device 20 may include, but is not limited to only including, a liquid crystal display (LCD) and/or a cathode ray tube (CRT). Input device 18 may be, but is not limited to being, a mouse and a keyboard. Memory device 14 may be a random access memory (RAM) and/or a read only memory (ROM). I/O interface 16 may be, but is not limited to being, a Universal Serial Bus (USB) port, a parallel port, or a serial port. Motor driver 32 may be, but is not limited to only being, a transistor, such as a bipolar junction transistor and/or a field effect transistor.

In the exemplary embodiment, computing device 12 transmits a signal to motor driver 32 and, upon receiving the signal, support 30 moves PCB 28 in a direction that is substantially parallel to an X-axis such that PCB 28 and support 30 are positioned under milling machine 22. When PCB 28 is positioned under milling machine 22, computing device 12 transmits a signal to milling machine 22 and, upon receiving the signal, milling machine 22 creates a hole (not shown) in PCB 28 having specific dimensions. In one embodiment, a user provides, via input device 18, to computing device 12, specific dimensions of a hole to be created within PCB 28.

After a hole is created within PCB 28, computing device 12 transmits a signal to motor driver 32 and upon receiving the signal, motor driver 32, via motor 34, repositions PCB 28 under adhesive dispenser 24. When PCB 28 is under adhesive dispenser 24, computing device 12 transmits a signal to adhesive dispenser 24 and upon receiving the signal, to enable an electrical component to be coupled to PCB 28, adhesive dispenser 24 dispenses an adhesive or multiple adhesives, such as, but not limited to, a soldering material and/or a rubber adhesive, onto a surface 38 of PCB 28 at one or more desired locations. Electrical components that may be coupled to PCB 28 include, but are not limited to only including, a synthetic jet member, a mounting pin, a control circuit, a sensing circuit, a power source, and/or a power converter.

After the adhesive has been dispensed across PCB 28, computing device 12 transmits a signal to motor driver 32 to move PCB 28 and support 30, via motor 32, such that PCB 28 is repositioned under pick-and-place machine 26. Computing device 12 then controls pick-and-place machine 26 to couple an electrical component and/or an electrical-mechanical component to PCB 28 at one or more of the desired locations identified on PCB 28. After each electrical component has been coupled to PCB 28, computing device 12 causes drive support 30 to move PCB 28 inside oven 36, wherein PCB 28 is heated to cure the adhesive such that each electrical component is securely coupled to PCB 28 via the cured adhesive.

Alternatively, a hole may be formed within PCB 28 at any stage of fabrication. For example, a hole may be formed within PCB 28 after one or more electrical components have been coupled to, or positioned relative to, PCB 28 at a desired position. In another alternative embodiment, a synthetic jet member is securely attached to PCB 28 via rubber adhesive and without heating PCB 28 in oven 36.

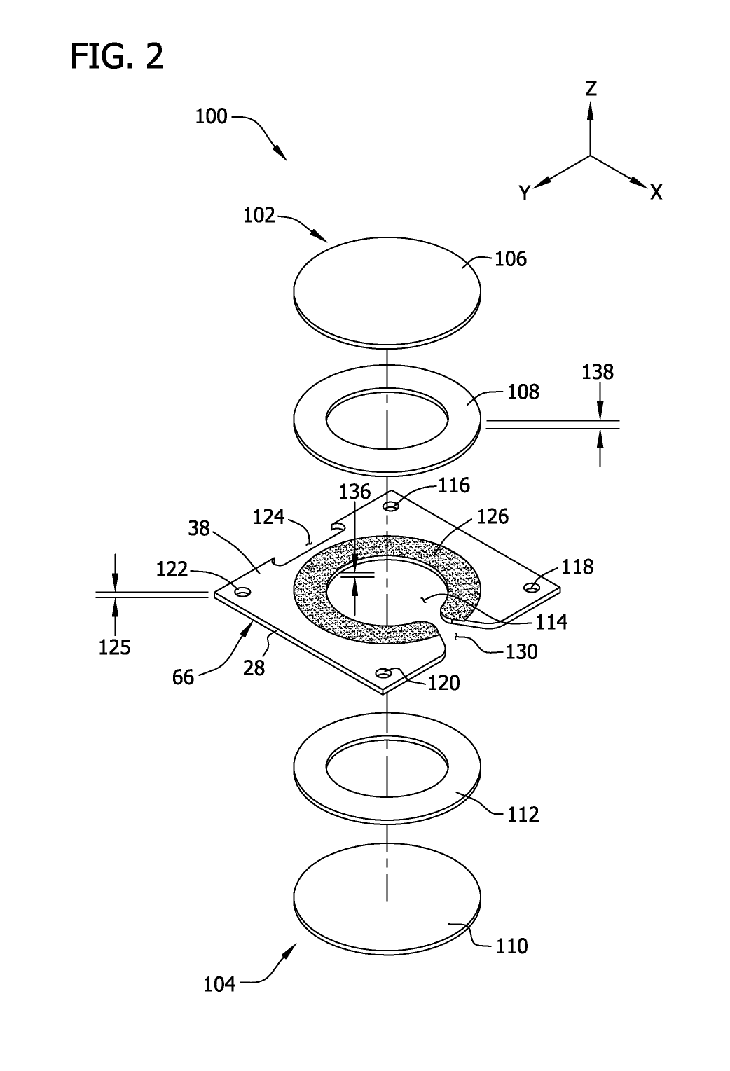

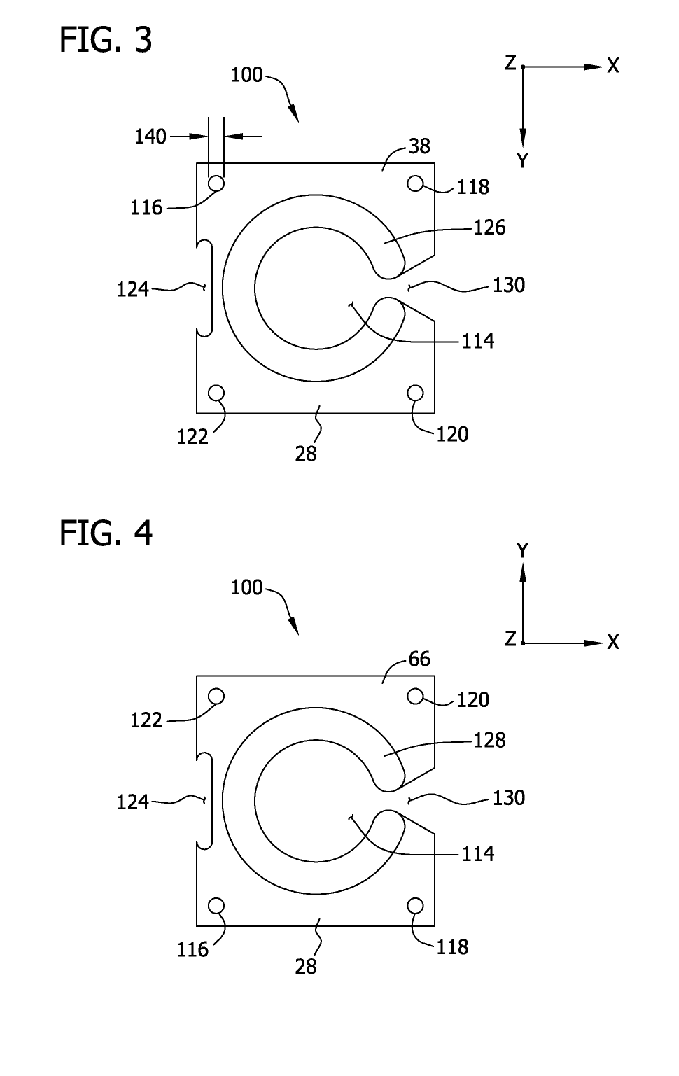

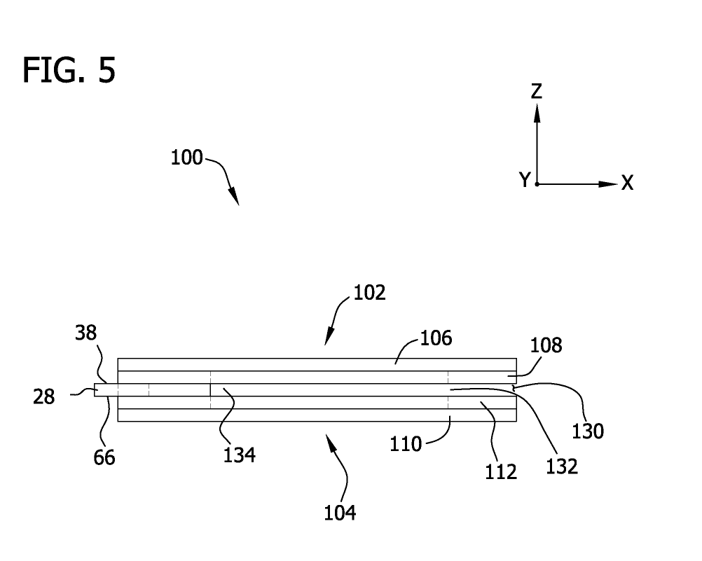

FIG. 2 is a perspective view of an exemplary synthetic jet assembly 100 fabricated using system 10 (shown in FIG. 1). FIG. 3 is a top view of PCB 28 and FIG. 4 is a bottom view of PCB 28. FIG. 5 is a side view of synthetic jet assembly 100. In the exemplary embodiment, synthetic jet assembly 100 includes a first synthetic jet member 102, a second synthetic jet member 104, and PCB 28. First synthetic jet member 102 is a diaphragm which includes an outer portion 106 that is fabricated from a piezoelectric material and an inner spacer 108 fabricated from a flexible material, such as an elastomer. More specifically, in the exemplary embodiment, outer portion 106 and inner spacer 108 are aligned substantially concentrically with respect to each other. Moreover, in the exemplary embodiment, each of outer portion 106 and inner spacer 108 are each substantially circular and are oriented substantially in an X-Y plane. In an alternative embodiment, first synthetic jet members 102 may be fabricated from a unitary contiguous material.

Similarly, second synthetic jet member 104 includes an outer portion 110 fabricated from a piezoelectric material. In the exemplary embodiment, first and second synthetic jet members 102 and 104 are fabricated from the same material. Second synthetic jet member 104 includes an inner spacer 112 fabricated from a flexible material. Again, in the exemplary embodiment, inner spacers 108 and 112 are fabricated from the same material. Moreover, in the exemplary embodiment, second synthetic jet member 104 is approximately the same size and shape as first synthetic jet member 102. PCB 28 is formed with a hole 114, and includes a plurality of mounting holes 116, 118, 120, and 122, and a slot 124.

Milling machine 22 forms hole 114 with specific dimensions and such that hole 114 extends through PCB 28. As such, hole 114 has a depth that is the same as a thickness 125 of PCB 28. In the exemplary embodiment, hole 114 is formed with a diameter 136 that is approximately the same as a diameter 138 of either inner spacer 108 and/or 112. In another embodiment, hole diameter 136 is larger than a diameter 138 of either inner spacer 108 and/or 112. In a further alternative embodiment, hole 114 is formed with a diameter 136 that is smaller than a diameter 138 of inner spacer 108 and/or 112. In the exemplary embodiment, hole 114 is formed with approximately the same cross-sectional shape as inner spacer 108 and/or 112. In yet another alternative embodiment, hole 114 is formed with a different cross-sectional shape than the cross-sectional shape of inner spacer 108 and/or 112.

Similarly, milling machine 22 forms mounting holes 116, 118, 120, and 122, and each of the mounting holes 116, 118, 120, and 122 with specific dimensions. For example, in the exemplary embodiment, a depth of mounting hole 116 is the same as PCB thickness 125. Moreover, in the exemplary embodiment, mounting hole 116, 118, 120, and 122 has a diameter 140 that is sized to receive a mounting pin (not shown) therein. The mounting pins are used to couple PCB 28 to a mounting surface (not shown), such as a second PCB. In an alternative embodiment, any number of mounting holes 116, 118, 120, and 122 are formed in PCB 28. In the exemplary embodiment, milling machine 22 also forms slots 124 and 130 within PCB 28. In an alternative embodiment, PCB 28 does not include slot 124.

Adhesive dispenser 24 dispenses adhesive across an upper portion 126 of PCB 28 and across a lower portion 128 of PCB 28. More specifically, adhesive dispenser 24 dispenses the adhesive on lower portion 128 after inverting or flipping PCB 28. In the exemplary embodiment, upper portion 126 is defined on top surface 38 and lower portion 128 is defined on bottom surface 66, and each portion 126 and 128 circumscribes at least a portion of hole 114.

Pick-and-place machine 26 positions first synthetic jet member 102 on the adhesive dispensed across upper portion 126, and positions second synthetic jet member 104 on the adhesive dispensed across lower portion 128. Specifically, pick-and-place machine 26 places second synthetic jet member 104 on adhesive dispensed across lower portion 128 after inverting PCB 28. More specifically, pick-and-place machine 26 positions first synthetic jet member 102 adjacent to upper portion 126 and second synthetic jet member 104 adjacent lower portion 128. Oven 36 heats the adhesive to securely couple first synthetic jet member 102 to upper portion 126 and second synthetic jet member 104 to lower portion 128. When first synthetic jet member 102 is securely coupled to upper portion 126 and second synthetic jet member 104 is securely coupled to lower portion 128, an orifice 130 and a cavity 132 are formed between first synthetic jet member 102 and second synthetic jet member 104. Cavity 132 is at least partially defined by hole 114 and extends to orifice 130. Moreover, when first synthetic jet member 102 is securely coupled to upper portion 126 and second synthetic jet member 104 is securely coupled to lower portion 128, a side wall 134 of synthetic jet assembly 100 is defined between first and second synthetic jet members 102 and 104. In the exemplary embodiment, side wall 134 is partially defined by a portion of PCB 28.

In an alternative embodiment, outer diaphragm 106 and inner spacer 108 of first synthetic jet member 102 are contoured, such as curved or polygonal or a combination of curved and polygonal shapes. For example, in the exemplary embodiment, a cross-sectional profile of each of outer diaphragm 106 and inner spacer 108 of first synthetic jet member 102 is substantially rectangular. In another embodiment, a cross-sectional profile of each of outer diaphragm 106 and inner spacer 108 is elliptical.

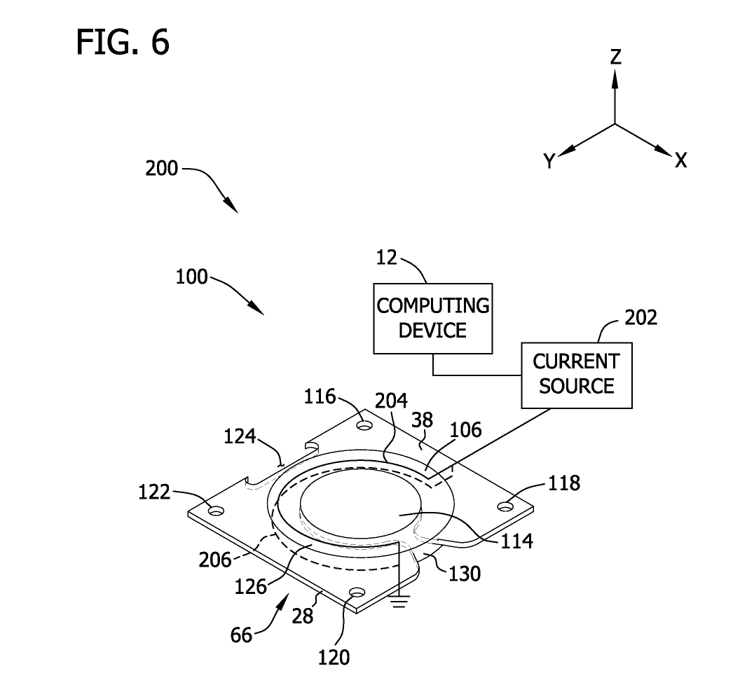

FIG. 6 is a diagram of an exemplary system 200 including a synthetic jet assembly 100. In the exemplary embodiment, system 200 includes computing device 12, a current source 202, and PCB 28. In one embodiment, current source 202 includes a transistor. In the exemplary embodiment, PCB 28 includes a resistor 204 that is embedded within top surface 38 and a resistor 206 that is embedded within bottom surface 66. More specifically, resistor 204 is embedded within top surface 38, along upper portion 126, and resistor 206 is embedded within bottom surface 66, along lower portion 128 (shown in FIG. 4).

After an adhesive, such as solder, has been dispensed across upper portion 126 and lower portion 128, computing device 12 controls current source 202 to cause resistors 204 and 206 to heat the adhesive such that synthetic jet member 102 is secured to upper portion 126 and synthetic jet member 104 is secured to lower portion 128. In such an embodiment, an oven is not used to cure the adhesive, but rather resistors 204 and 206 are used to heat the adhesive laid on portions 126 and 128. In an alternative embodiment, such a self-heating configuration may be used to couple any electrical or electrical-mechanical component to PCB 28.

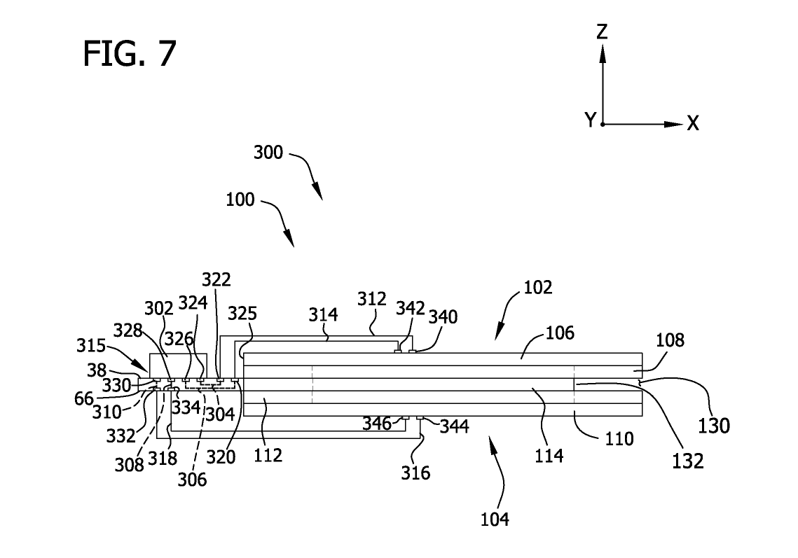

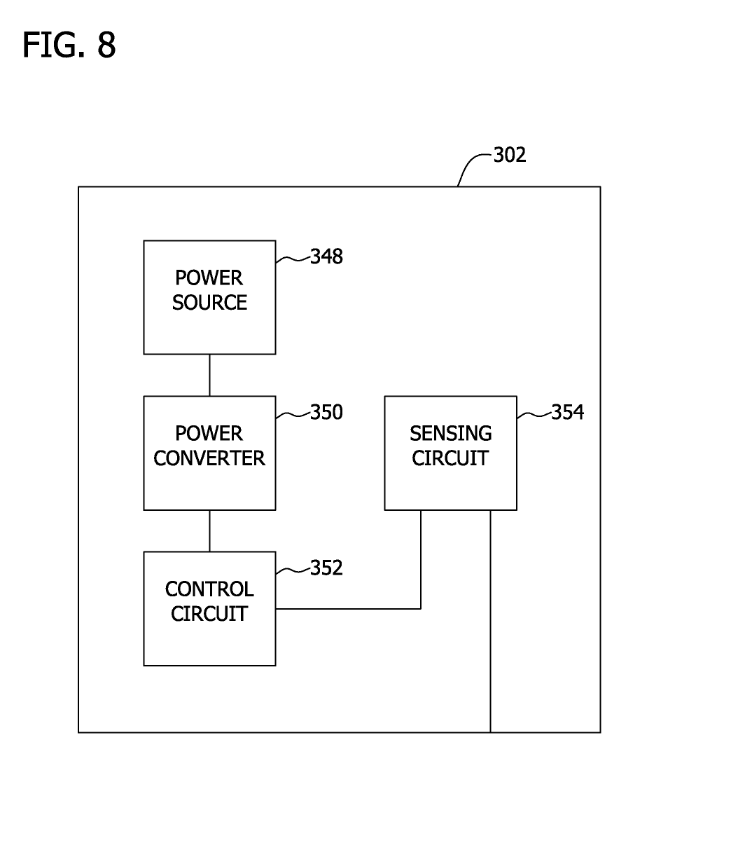

FIG. 7 is a side view of an exemplary system 300 including a synthetic jet assembly 100. FIG. 8 is a block diagram of an integrated circuit 302 that is included in system 300. In the exemplary embodiment, system 300 includes a plurality of wire traces 304, 306, 308, and 310 embedded within PCB 28, a plurality of interconnects 312, 314, 316, and 318, a plurality of PCB contacts 320, 322, 324, 326, 328, 330, 332, and 334, and a plurality of disc contacts 340, 342, 344, and 346 fabricated from a metallic material. In one embodiment, disc contacts 340 and 342 are securely coupled to outer diaphragm 106. In another embodiment, disc contacts 344 and 346 are securely coupled to outer spacer 112. Integrated circuit 302 includes one or more electronic devices, such as, in the exemplary embodiment, a power source 348, a power converter 350, a control circuit 352, and a sensing circuit 354. Power source 348 may be a direct current (DC) power source or an alternating current (AC) power source that provides power to control circuit 352 and/or to sensing circuit 354. Power converter 350 converts the power to an amplitude and/or frequency that is compatible with control circuit 352 and/or sensing circuit 354. In an alternative embodiment, system 300 does not include sensing circuit 354, PCB contacts 320, 326, 330, and 332, wire traces 306 and 310, disc contacts 342 and 344, or interconnects 314 and 316.

In the exemplary embodiment, PCB 28 is fabricated from a flame retardant 4 (FR-4) material, an FR-2 material, polyimide material, or a G10 material. In one embodiment, control circuit 352 is a signal generator or a processor, and power source 348 includes a voltage source and/or a current source. Sensing circuit 354 may include a velocity sensor, a position sensor, a piezoelectric motion sensor, and/or a voltage sensor. Sensing circuit 354 may also include an analog-to-digital converter and/or a signal conditioning circuit, such as an amplifier and a filter.

PCB contacts 320, 322, 324, 326, 328, and 330 are embedded within top surface 38 and PCB contacts 332 and 334 are embedded within bottom surface 66. Control circuit 352 is coupled to inner diaphragm 108 via PCB contacts 322 and 324, wire trace 304, interconnect 312, and disc contact 340. Moreover, control circuit 352 is coupled to inner spacer 112 via PCB contacts 328 and 334, wire trace 308, interconnect 318, and disc contact 346. Similarly, sensing circuit 354 is coupled to inner spacer 108 via interconnect 314, PCB contacts 320 and 326, wire trace 306, and disc contact 342, and sensing circuit 354 is coupled to inner spacer 112 via interconnect 316, PCB contacts 330 and 332, wire trace 310, and disc contact 344. In the exemplary embodiment, control circuit 352 includes a digital-to-analog converter that converts a digital signal transmitted by control circuit 352 to inner spacer 108 and/or 112 to an analog signal.

Computing device 12 (shown in FIG. 1) controls adhesive dispenser 24 (shown in FIG. 1) to dispense the adhesive, such as solder, at desired locations on PCB contacts 320, 322, 324, 326, 328, 330, 332, and 334, and on disc contacts 340, 342, 344, and 346. Computing device 12 also causes adhesive dispenser 24 to dispense the adhesive at desired locations on PCB contacts 332 and 334, and on disc contacts 344 and 346 after pick-and-place machine 26 (shown in FIG. 1) inverts PCB 28 to face bottom surface 66 in the Z-direction. Moreover, computing device 12 causes pick-and-place machine 26 to place integrated circuit 302 with pin-outs onto the adhesive placed onto PCB contacts 324, 326, 328, and 330. For example, a first pin-out of integrated circuit 302 is coupled to sensing circuit 354 and is positioned in the adhesive coupled to sensing circuit 354 and is positioned in the adhesive dispensed across PCB contact 330.

Oven 36 (shown in FIG. 1) heats the adhesive dispensed across PCB contacts 320, 322, 324, 326, 328, 330, 332, and 334, and across disc contacts 340, 342, 344, and 346 to securely couple interconnects 312 and 314 to respective disc contacts 340 and 342, interconnects 312 and 314 to respective PCB contacts 322 and 320, interconnects 316 and 318 to respective disc contacts 344 and 346, interconnects 316 and 318 to respective PCB contacts 332 and 334, and integrated circuit 302 to PCB 28. For example, oven heats the adhesive across PCB contacts 324, 326, 328, and 330 to securely couple the first pin-out of sensing circuit 354 with PCB contact 326, the second pin-out of sensing circuit 354 with PCB contact 330, the first pin-out of control circuit 352 with PCB contact 324, and the second pin-out of control circuit 352 with PCB contact 328.

Integrated circuit 302 establishes an electrical connection with inner diaphragm 108 when integrated circuit 302 is securely coupled to PCB contacts 324, 326, 328, and 330, interconnect 312 is securely coupled to disc contact 340 and PCB contact 322, and interconnect 314 is securely coupled to disc contact 342 and PCB contact 320. Moreover, integrated circuit 302 establishes an electrical connection with diaphragm 110 when integrated circuit 302 is securely coupled to PCB contacts 324, 326, 328, and 330, interconnect 316 is securely coupled to disc contact 344 and PCB contact 332, and interconnect 318 is securely coupled to disc contact 346 and PCB contact 334. A keepout area 315 is occupied by integrated circuit 302 on PCB top surface 38.

Control circuit 352 transmits a signal to diaphragm 106 via PCB contact 324, wire trace 304, PCB contact 322, interconnect 312, and disc contact 340, and transmits a signal to diaphragm 110 via PCB contact 328, wire trace 308, PCB contact 334, interconnect 318, and disc contact 346. Upon receiving a signal from control circuit 352, diaphragm 106 vibrates with a frequency of the signal. Moreover, upon receiving a signal from control circuit 352, diaphragm 110 vibrates with a frequency of the signal. As either diaphragms 106 and/or 110 contracts towards cavity 132 during the vibrations, a medium, such as air, within cavity 132 is discharged via orifice 130 into outside cavity 132 and towards an electronic device (not shown) to facilitate cooling the electronic device. Moreover, as either diaphragm 106 and/or 110 expands away from cavity 132 during the vibrations, a medium, such as cool air, from outside cavity 132 enters into cavity 132 via orifice 130.

Moreover, as either diaphragm 106 and/or 110 vibrates, sensing circuit 354 senses a velocity of the vibration, a position of the vibration, a voltage generated from the vibration, and/or a current generated by the vibration to output a feedback signal. The feedback signal received from sensing circuit 354 may be analyzed by control circuit 352 to determine, for example, whether to increase or decrease an amount of vibration induced to either diaphragm 106 and/or 110.

In an alternative embodiment, sensing circuit 354 is a thermal sensor that senses an amount of heat generated by an electronic device (not shown) and transmits a signal representative of the amount of heat generated to control circuit 352. In such an embodiment, the thermal sensor may be coupled to an electronic device (not shown) or may be coupled to a heat sink coupled in communication with the electronic device. Moreover, the thermal sensor is not coupled to either diaphragm 106 or diaphragm 110. In another embodiment, as either diaphragm 106 and/or 110 contracts towards cavity 132, a medium, such as air within cavity 132 is discharged via orifice 130 towards a heat sink coupled to an electronic device to facilitate cooling the electronic device.

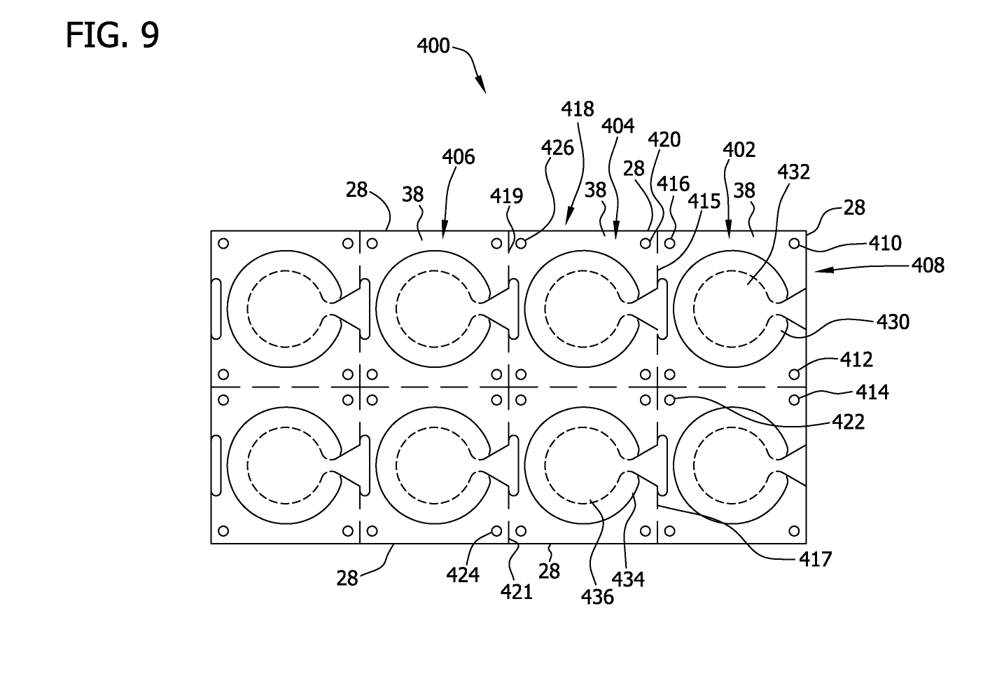

FIG. 9 is a top-view of an exemplary system 400 including a plurality of synthetic jet assemblies, such as synthetic jet assemblies 100 (shown in FIG. 2). In the exemplary embodiment, system 400 includes PCB 28 and a plurality of synthetic jet members 402, 404, and 406. A portion 408 of system 400 includes a plurality of mounting holes 410, 412, 414, and 416. Similarly, a portion 418 of system 400 includes a plurality of mounting holes 420, 422, 424, and 426. Portion 408 is separated from portion 418 by a pair of score lines 415 and 417. Portion 408 includes synthetic jet member 402 and portion 418 includes synthetic jet member 404. Moreover, portion 418 is separated from remaining portions of system 400 by score lines 415, 419, and 421. In the exemplary embodiment, synthetic jet member 402 includes an outer section 430. Similarly, synthetic jet member 404 includes an outer section 434. In the exemplary embodiment, milling machine 22 (shown in FIG. 1) creates score lines 415, 417, 419, and 421 under control of computing device 12. A user may manually separate portion 408 from portion 418, and separate portion 418 from the remaining portions of system 400.

System 400 can be fabricated in a variety of ways. For example, in one embodiment, adhesive dispenser 24 (shown in FIG. 1) securely couples synthetic jet member 402 to an upper portion (not shown), such as upper portion 126 (shown in FIG. 2), of PCB 28. Adhesive dispenser 26 also securely couples synthetic jet member 404 to PCB 28 before securely coupling a bottom synthetic jet member (not shown), such as synthetic jet member 104 (shown in FIG. 2), within portion 408, to a lower portion (not shown), such as lower portion 128 (shown in FIG. 4) of bottom surface 66 (shown in FIG. 4). In another embodiment, adhesive dispenser 24 securely couples synthetic jet member 402 to an upper portion (not shown), such as upper portion 126 (shown in FIG. 2), of PCB 28 and a bottom synthetic jet member (not shown) to a lower portion (not shown), such as lower portion 128 (shown in FIG. 4), of portion 408 before securely coupling synthetic jet member 404 to PCB 28.

In yet another embodiment, milling machine 22 forms all mounting holes, such as mounting holes 410, 412, 414, 416, 420, 422, 424, and 426 before securing any synthetic jet members, such as synthetic jet members 402 and/or 404, to PCB 28. In another alternative embodiment, milling machine 22 forms a hole (not shown), such as hole 114 (shown in FIG. 2), within PCB 28 before adhesive dispenser 24 securely couples synthetic jet member 402 to PCB 28.

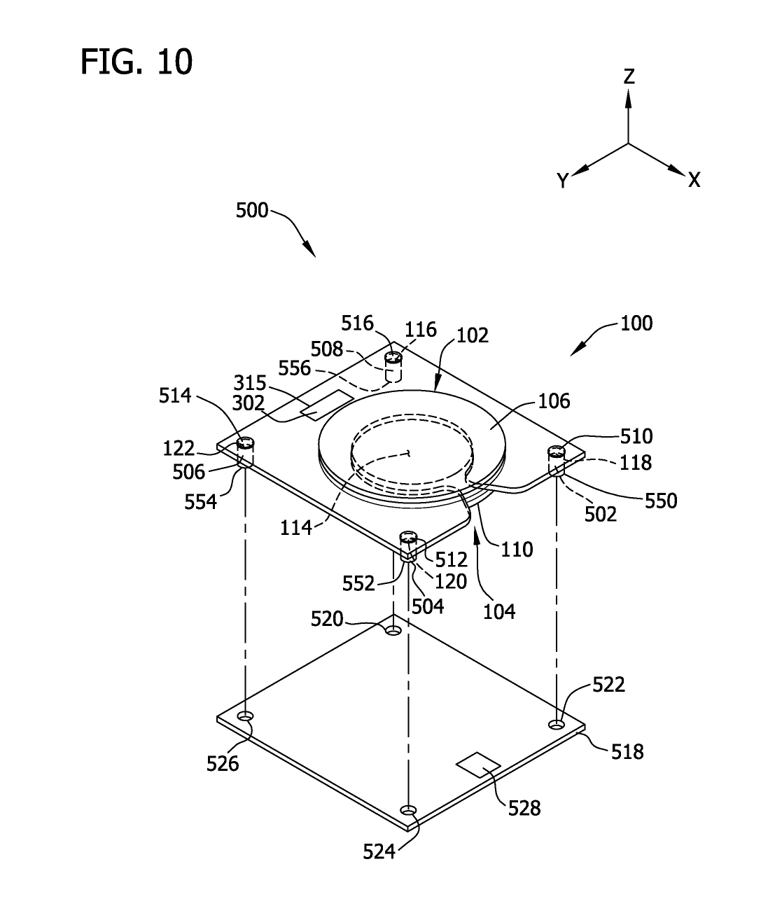

FIG. 10 is an exploded view of an exemplary system 500 including synthetic jet assembly 100. System 500 also includes a plurality of mounting pins 502, 504, 506, and 508, a plurality of bushings 510, 512, 514, and 516, a PCB 518, and a plurality of mounting positions 520, 522, 524, and 526 on PCB 518. An electronic device 528 coupled to PCB 518. Electronic device 528 may be, but is not limited to being, a heat generating device, such as a central processing unit or processor (CPU), a power source, a power converter, and a phase locked loop. In the exemplary embodiment, each bushing 510, 512, 514, and 516 may be fabricated from an elastic material, such as rubber.

Adhesive dispenser 24 (shown in FIG. 1) dispenses adhesive across mounting positions 520, 522, 524, and 526. Pick-and-place machine 26 (shown in FIG. 1) then positions mounting pins 502, 504, 506, and 508 to extend through respective bushings 510, 512, 514, and 516. Mounting pins 502, 504, 506, and 508 are then extended through respective mounting holes 118, 120, 122, and 116, and into respective mounting positions 522, 524, 526, and 520 defined on PCB 518. System 500 then is heated to securely couple pins 502, 504, 506, and 508 within respective mounting positions 520, 522, 524, and 526. After being securely coupled to PCB 518, synthetic jet assembly 100 can be used to facilitate cooling electronic device 528 as described above.

In the exemplary embodiment, mounting pins 502, 504, 506, and 508 are identical. In an alternative embodiment, at least one mounting pin 502, 504, 506, and/or 508 is a different size than the remaining mounting pins 502, 504, 506, and/or 508. In another alternative embodiment, any other fastening or coupling mechanism may be used to securely couple synthetic jet assembly 100 to PCB 518. For example, in one embodiment, mounting pins 502, 504, 506, and/or 508 may be secured to PCB 518 using a soldering process. In other embodiments, synthetic jet assembly 100 may be coupled to PCB 518 via a mechanism, such as, an elastomeric tab, an elastomeric clip, a flexible connector, a metal bracket, a mounting ring, a mounting post, a mounting screw, and a mounting tab.

Technical effects, such as advantages, of the systems and methods described herein include automating a process of manufacturing a synthetic jet using a computing device, a milling machine, an adhesive dispenser, and a pick-and-place machine. In addition, the systems and methods described herein facilitate mass production of synthetic jets in a cost effective and reliable manner. Other technical effects include providing an integrated circuit with a synthetic jet assembly as a single module on a printed circuit board such that space occupied by the integrated circuit outside the PCB is saved. Moreover, the automated production of synthetic jet assemblies on the PCB is less tedious as compared to known manual methods of assembling similar devices.

Exemplary embodiments of methods and systems for manufacturing a synthetic jet are described above in detail. The methods and systems are not limited to the specific embodiments described herein. For example, the methods and systems may be used in combination with other electrical systems.

While various embodiments of the invention have been described, those skilled in the art will recognize that modifications of these various embodiments of the invention can be practiced within the spirit and scope of the claims.

What is claimed is:

1. A method for manufacturing a synthetic jet assembly, said method comprising forming a hole extending through a portion of a first printed circuit board (PCB), wherein the hole defines a portion the synthetic jet assembly, and wherein the hole is positioned to enable the synthetic jet assembly to facilitate cooling a component coupled to a second PCB.

2. A method in accordance with claim 1, further comprising coupling a first synthetic jet member about a portion of the hole on a first side of the first PCB.

3. A method in accordance with claim 2, further comprising coupling a second synthetic jet member about a portion of the hole on a second side of the PCB that is opposite the first side of the first PCB.

4. A method in accordance with claim 1, further comprising coupling a first synthetic jet member to an upper surface of the first PCB such that the first synthetic jet member at least partially circumscribes the hole.

5. A method in accordance with claim 4, further comprising coupling a second synthetic jet member to a lower surface of the first PCB such that the second synthetic jet member at least partially circumscribes the hole.

6. A method in accordance with claim 5, further comprising creating an orifice extending from the hole in the first PCB by coupling the first synthetic jet member to the upper surface and by coupling the second synthetic jet member to the lower surface.

7. A method in accordance with claim 5, further comprising defining a side wall of the synthetic jet assembly between the first synthetic jet member and the second synthetic jet member by coupling the first synthetic jet member to the upper surface and by coupling the second synthetic jet member to the lower surface.

8. A method in accordance with claim 5, further comprising coupling an integrated circuit to the first PCB.

9. A method in accordance with claim 8, further comprising controlling operation of at least one of the first synthetic jet member and the second synthetic jet member by transmitting a signal from the integrated circuit to at least one of the first synthetic jet member and the second synthetic jet member.

10. A method in accordance with claim 8, wherein the integrated circuit includes a control circuit and a power source, said method further comprises:
actuating at least one of the first synthetic jet member and the second synthetic jet member by transmitting a signal from the control circuit; and
providing power from the power source to the control circuit.

11. A method in accordance with claim 8, wherein the integrated circuit includes a control circuit and a sensing circuit, said method further comprises:
actuating at least one of the first synthetic jet member and the second synthetic jet member by transmitting a signal from the control circuit; and
sensing an output of at least one of the first synthetic jet member and the second synthetic jet member using the sensing circuit.

12. A method in accordance with claim 1, further comprising:
coupling a first synthetic jet member to an outer surface of the first PCB; and
integrating a resistive element along a periphery of the first synthetic jet member.

13. A method in accordance with claim 12, further comprising:
depositing an adhesive across at least a portion of the resistive element; and
securely coupling the first synthetic jet member to the first PCB via the adhesive.

14. A synthetic jet assembly comprising a first printed circuit board (PCB) comprising a hole extending through a portion of said first PCB, wherein said hole defines a portion of said synthetic jet assembly, and wherein said hole is positioned to enable said synthetic jet assembly to facilitate cooling a component coupled to a second PCB.

15. A synthetic jet assembly in accordance with claim 14, further comprising:
a first synthetic jet member coupled to an upper surface of said first PCB such that said first synthetic jet member at least partially circumscribes said hole; and
a second synthetic jet member coupled to a lower surface of said first PCB such that said second synthetic jet member at least partially circumscribes said hole.

16. A synthetic jet assembly in accordance with claim 15, further comprising:
an orifice extending from said hole; and
a side wall defined between said first synthetic jet member and said second synthetic jet member.

17. A synthetic jet assembly in accordance with claim 15, further comprising an integrated circuit coupled to said first PCB, wherein said integrated circuit is configured to control operation of at least one of said first synthetic jet member and said second synthetic jet member.

18. A system for manufacturing a synthetic jet assembly, said system comprising a milling machine configured to form a hole extending through a portion of a first printed circuit board (PCB), wherein the hole defines a portion of the synthetic jet assembly, and wherein said milling machine is configured to form the hole in a positioned that enables the synthetic jet assembly to facilitate cooling a component coupled to a second PCB.

19. A system in accordance with claim 18, further comprising a pick-and-place machine configured to position a first synthetic jet member in relation to an upper surface of the first PCB such that the first synthetic jet member at least partially circumscribes the hole and to position a second synthetic jet member in relation to a lower surface of the first PCB such that the second synthetic jet member at least partially circumscribes the hole.

20. A system in accordance with claim 19, wherein said pick-and-place machine is further configured to position an integrated circuit in relation to the first PCB, wherein the integrated circuit is configured to control operation of at least one of the first synthetic jet member and the second synthetic jet member.
